(19) United States
(12) Patent Application Publication
(10) Pub. No.: US 2016/0288291 A1
(43) Pub. Date: Oct. 6, 2016

(54) METHOD FOR GRINDING WAFERS BY SHAPING RESILIENT CHUCK COVERING

(71) Applicant: Strasbaugh, Inc., San Luis Obispo, CA (US)

(72) Inventor: Salman M. Kassir, Paso Robles, CA (US)

(21) Appl. No.: 14/673,479

(22) Filed: Mar. 30, 2015

(51) Int. Cl. B24B 37/30; B24B 37/04; H01L 21/304; B24B 7/22

(52) U.S. Cl. CPC B24B 37/30; B24B 7/228; B24B 37/042; H01L 21/304

(57) ABSTRACT

A method for facilitating and improving the production of quality thin wafers by adhering traditional resilient back-grind tape that has been perforated over the area that will contact the wafer on the ceramic porous grind chuck, so as to allow a vacuum to be applied to the wafer back surface to hold the wafer for processing. The tape adhering to a first surface of the chuck is ground with an abrasive grind wheel, bringing the surface of the tape parallel to the chuck surface which was previously ground by the same grinding device. The wafer is then flipped over and placed on the chuck, the second surface of the wafer then being ground. Grinding the tape while it is mounted on the chuck establishes the plane perpendicular to the grind wheel spindle, removes the bumpiness from the perforation holes and evens out the non-uniformity of the tape, resulting in improved wafer back side grinding and thus good site flatness.

### RELATED APPLICATIONS

This application is a continuation-in-part of application Ser. No. 13/573,148, filed Aug. 27, 2012.

### BACKGROUND OF THE INVENTION

1. Field of the Invention

The present invention is utilized in the manufacture of semiconductor material wafers without components on the front side and in particular, a method and apparatus for preventing the wafer from distorting during the planarization steps by attaching a grindable resilient tape to a porous grind chuck or hard chuck with discrete vacuum holes, grinding the tape and then placing a wafer on the chuck for processing.

2. Description of the Prior Art

The semiconductor industry has, and is, interested in producing material wafers with very low total thickness variation (TTV) from wafers that are uneven in thickness, post wire sawing for example. Most wafers are cut from their growth boule using a high production wire-sawing method that inherently produce waviness and high TTV due to the irregular motion of the wire position as the boule is turned. This waviness and sometime highly irregular wafer shape after sawing presents subsequent difficulties especially for batch processes.

U.S. Pat. No. 6,866,564 to Strasbaugh et al, assigned to the assignee of the present invention, discloses a method of back-grinding device-mounted wafers wherein a resilient back grinding component, such as a tape or pad, is applied to the surface of a solid chuck. The component is held to the chuck surface as each wafer is sequentially placed on the component and after grinding the backside of the wafer, each wafer is removed from the chuck. This patent applies to thinning wafers, such as those made from silicon, for final packaging to facilitate the process by eliminating the taping and de-taping of thin device wafers, and to save the cost associated with this step.

U.S. Pat. No. 5,964,646, assigned to the assignee of the present discloses a method and apparatus for planarizing silicon wafers initially having wavy surfaces. A vacuum is applied to one side of a porous ceramic plate, and a perforated resilient pad is affixed to the opposite side of the porous ceramic plate. A vacuum extends through the perforations on the resilient pad to permit a wafer to be mounted on the exposed side of the resilient pad. The wafer is not deformed while being held in place for grinding and thus the wafer has no tendency to spring back to its original wavy shape. Once one side of the wafer has been planarized, the second wafer surface is planarized on a flat chuck to provide a wafer that has uniform thickness.

U.S. Pat. No. 8,025,553 to Sekiya discloses a method for back grinding a wafer wherein the face-side surface of the wafer is covered with a resin film, the surface of the resin film being cut to form a flat surface parallel to the face-side surface of the wafer. The wafer is held with the surface of the resin film in contact with a suction surface of a chuck table in a grinding apparatus, and the exposed backside surface of the wafer is ground. Unevenness in thickness of the resin film is suppressed, the thickness of the wafer subjected to back grinding as a result being made uniform.

Although the above-noted patents disclose various techniques for maintaining a uniform wafer thickness, the total thickness (TTV) variation is too high to meet the requirements of new chip technology.

What is desired is to provide a method for treating wafers wherein the TTV is reduced to the point that it meets the requirements of thin semiconductor manufacturers for producing semiconductor chips that can be used in various devices, such as MP3 players, televisions, etc.

### SUMMARY OF THE INVENTION

The present invention provides a method of producing semiconductor material wafers with very low TTV from wafers that are uneven in thickness.

Specifically, a soft chuck surface is prepared with the soft chuck being of semiconductor production compatible clean-room material whose surface characteristics can be altered with holes for facilitating vacuum and via grinding and/or polishing to form a planar surface parallel to the cutting plane of either grinding (grind wheel plane) or polishing (pad plane).

This method facilitates and improves the first side planarization of a substrate of any shape by adhering traditional resilient back-grind tape (such as Ultron 1034R-9.8 or Ultron 1044R-9.8) that has been perforated for example, by a laser punching over the area that will contact the wafer on to the ceramic porous grind chuck, so as to allow vacuum to be applied to the wafer back surface (i.e., surface facing the chuck) to hold the wafer for processing. The tape adhering to the chuck is ground with an abrasive grind wheel, bringing the surface of the tape parallel to the chuck surface which was previously ground by the same grinding wheel. The act of grinding the tape while it is mounted on the chuck establishes the plane perpendicular to the grind spindle rotational axis, removes the bumpiness from the perforation holes and evens out the non-uniformity of the tape application onto the chuck, which attachment normally being highly operator dependent, resulting in improved wafer first side grinding and thus good site flatness.

### DESCRIPTION OF THE DRAWINGS

For a better understanding of the present invention as well as other objects and further features thereof, reference is made to the following description which is to be read in conjunction with the accompanying drawing therein:

FIGS. 1(a)-1(g) illustrate the steps of backgrinding wafers in accordance with the teachings of the present invention; and

FIGS. 2(A)-2(B) are illustrative of how non-uniformities in a tape surface are corrected after grinding.

### DESCRIPTION OF THE INVENTION

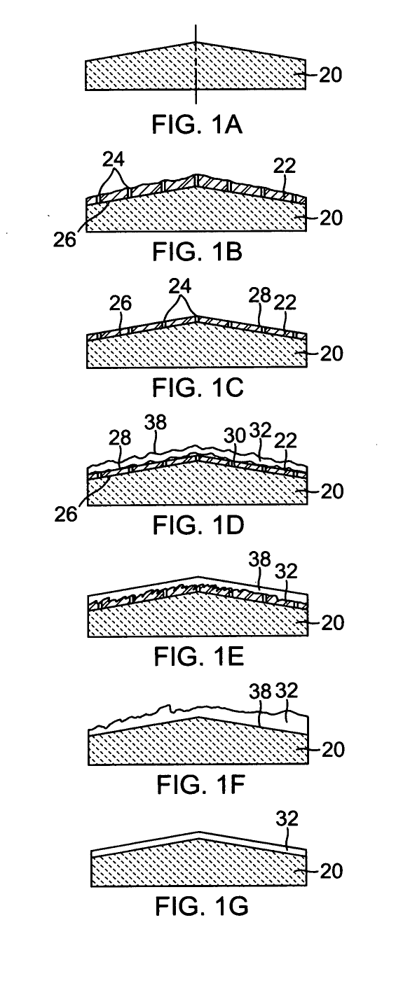

Referring to FIGS. 1(a)-1(g), the steps of grinding the wafer in accordance with the teachings of the present invention is illustrated.

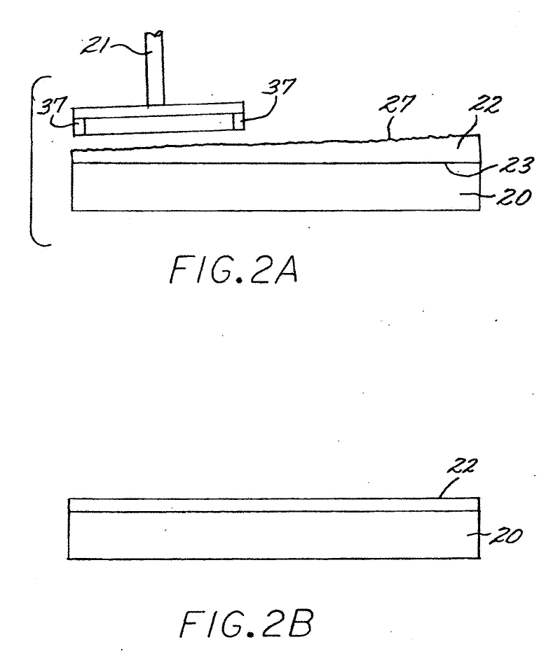

A porous ceramic chuck 20 is first ground to the desired shape (FIG. 1A) and then a flexible tape 22 with holes 24 formed therein is placed on the top surface 26 of chuck 20 (FIG. 1B). The area of the tape that interfaces with surface 26 is referred to as the “soft” chuck surface. FIG. 2A illustrates, in simplified form, when tape 22 is first applied to chuck 20.

The upper surface 28 of tape 22 is then ground by grinder 21 parallel to surface 26 (FIG. 1C). The bottom surface 30 of wafer 32 (shown to have a wavy shape) is then positioned in contact with the upper surface 28 of tape 22 and a vacuum is applied through holes 24 to secure wafer 32 to tape 22 (FIG. 1d). Surface 38 of wafer 32 is then ground (FIGS. 1d and 1e) producing a wafer with a surface parallel to the chuck top surface 26. The wafer is then removed from the tape and then turned over and the ground surface 38 of wafer 32 placed on the upper chuck surface (FIG. 1f), the second surface of wafer 32 then also being ground (FIG. 1g). To grind the second surface, wafer 32 is placed on hard chuck 31 (with no binding tape).

The purpose of grinding tape 22 is to correct any anomaly that might be associated with applying the tape to the chuck surface since this is usually a manual step depending on the skill of the operator performing the grinding step. In addition, the tape itself typically has some degree of non-uniformity that is corrected by the grinding step.

A more detailed description of the process set forth hereinabove follows:

The grind chuck 20, porous as illustrated, is prepared by pre-grinding a small amount from the surface using the abrasive grind wheel 37 (FIG. 2A) thus cleaning the chuck 20 and shaping the chuck as desired to produce a flat wafer surface. A suitable resilient plastic background tape of predetermined thickness (the hardness of the tape is dependent on the tape selected) 22 is selected such that unwanted bumps or ridges on the wafer back can be “absorbed” by the soft tape rather than protruding from the top surface upwards (the preferred thickness range of the tape is 130 um to about 300 um). The tape sheet is cut into a size and shape to fit exactly onto the grind chuck surface and then perforated with small holes (a laser punch may be utilized). The holes cover the chuck contact area and are about one millimeter apart in a uniform pattern.

The film that protects the adhesive on the back of the tape (not shown) is then removed and the perforated tape 22 is then attached to the entire surface of grind chuck 20 with the perforated area aligned where the wafer 32 will be attached by vacuum for surface grinding or polishing. Alternatively, perforated tape holes can be aligned with holes in the top surface of a hard chuck so as to facilitate vacuum attachment onto a solid chuck rather than a porous ceramic chuck. The top tape surface is then ground with a light down force (typically less than 4 pounds) to remove bits of debris caused by perforation holes generated by the laser and to shape the top surface of the tape. The wafer 32 to be ground is then placed on the perforated portion of the tape and attached by applying vacuum from below the chuck. With the wafer held firmly, a predetermined amount of wafer material from the top side of the wafer is ground so that the wafer achieves its desired shape. The wafer 32 is then removed from the chuck, turned over and then placed on the upper surface of the chuck. The exposed surface of the wafer is then ground to a predetermined thickness.

In a preferred mode of operation; two separate chucks are utilized, a “soft” chuck surface (covered by the grinding tape) and a “hard” chuck surface (grinding tape is not utilized). The first side of the wavy shaped wafer is ground on the soft chuck. After grinding the first side, the wafer is flipped over and placed on the hard chuck, the second wafer side then being ground. The purpose of the soft chuck is to absorb the waviness to avoid print-through (the waves on the backside of the wafer show on the front side of the wafer after grinding). When the second side is ground, the hard chuck is necessary to provide a solid, flat reference to obtain the necessary flatness after the second grind. In summary, the wafer is removed from the soft work chuck, flipped and placed on the hard work chuck for the second side grind.

The grinding platform utilized in the Strasbaugh 7AF grinder may be utilized to grind the tape. Using the same grinder to shape the tape that was used to shape the grind chuck enables a precise tape surface parallel to the contacting chuck surface to be fabricated which meets the stringent dimensional requirements of wafer manufacturers.

FIGS. 2A and 2B are simplified representations of how the surface of tape 22 is ground by grinder 21. Tape 22 is first applied to chuck 20 where a first surface 23 of tape 22 is placed in contact with surface 25 of chuck 20. Surface 27 of tape 22 is shown as being uneven (FIG. 2A).

FIG. 2B illustrates top surface 27 of tape 22 after it ground with wheel 37.

Typical resilient back-grind tape that has been successfully utilized is Ultron® tape 1034R-9.8 and Ultron® tape 1044R-9.8, distributed by Ascend Performance Materials Operations LLC, Houston, Tex.

The process of the present invention thus enables semiconductor wafers to be produced of superior uniform thickness from various materials.

It should be noted that this planarization concept also applies to polishing whereby the carrier film that is currently used for wafer backing during polish, such as the Strasbaugh DF200, can be replaced with a malleable tape that can be polished to remove the non-uniformity associated with material and operator applications.

While the invention has been described with reference to its preferred embodiments, it will be understood by those skilled in the art that various changes may be made and equivalents may be substituted for elements thereof without departing from the true spirit and scope of the invention. In addition, many modifications may be made to adapt a particular situation or material to the teachings of the invention without departing from its essential teachings.

What is claimed is:

1. A method of grinding a first wafer having first and second surfaces comprising the steps of:
providing a first grind chuck having first and second surfaces;
providing a first resilient member having top and bottom surfaces;
cutting the resilient member to a size and shape that conforms to said first surface of said chuck;
placing said bottom surface of said resilient member on the first surface of said chuck;
grinding the top surface of the resilient member to shape and smooth the top surface thereof utilizing a first grinding apparatus;
placing said first wafer on said top surface of said resilient member;
securing said first wafer to said grind chuck;
grinding said first surface of said first wafer to the desired shape using said first grinding apparatus.
providing a second grind chuck having first and second surfaces; and
removing said first wafer from said first grinding chuck and inverting said wafer such that the second surface thereof faces the first surface of said second grind chuck.

2. The method of claim 1 wherein openings are formed in said resilient member.

3. The method of claim 1 wherein said grinding chuck is porous.

4. The method of claim 1 wherein openings are formed in said grind chuck.

5. The method of claim 3 wherein said second surface of said wafer is ground by said first grinding apparatus.

6. The method of claim 1 further including the step of replacing said first wafer with a second wafer.

7. The method of claim 1 wherein said first resilient member is removed from said ground chuck and replaced with a second resilient member.

8. The method of claim 7 wherein said second resilient member is processed in the same manner as said first resilient member.

9. The method of claim 1 wherein said resilient member comprises a tape.

10. The method of claim 1 wherein said second surface of said wafer is ground on said second grind chuck.
